(19) United States
(12) Patent Application Publication
(10) Pub. No.: US 2010/0148280 A1
(43) Pub. Date: Jun. 17, 2010

(54) SEMICONDUCTOR DEVICE AND METHOD FOR FABRICATING THE SAME

(75) Inventor: Riichirou Mitsuhashi, Toyama (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/711,800

(22) Filed: Feb. 24, 2010

Related U.S. Application Data
(63) Continuation-in-part of application No. PCT/JP2009/003079, filed on Jul. 2, 2009.

(30) Foreign Application Priority Data
Oct. 21, 2008 (JP) 2008-270416

(51) Int. Cl. H01L 29/78; H01L 21/336

(52) U.S. Cl. 257/410; 438/591; 438/287; 257/E21.409; 257/E29.255

(57) ABSTRACT

A semiconductor device includes a semiconductor substrate, a gate insulating film formed on a semiconductor substrate and containing a first element and a second element, and a gate electrode formed on the gate insulating film. The gate insulating film has a higher content of the first element in a portion thereof closer to the semiconductor substrate than in a portion thereof closer to the gate electrode, and a higher content of the second element in a portion thereof closer to the gate electrode than in a portion thereof closer to the semiconductor substrate.

### CROSS-REFERENCE TO RELATED APPLICATIONS

This is a continuation of PCT International Application PCT/JP2009/003079 filed on Jul. 2, 2009, which claims priority to Japanese Patent Application No. 2008-270416 filed on Oct. 21, 2008. The disclosures of these applications including the specifications, the drawings, and the claims are hereby incorporated by reference in their entirety.

### BACKGROUND

The present disclosure relates to semiconductor devices and methods for fabricating the semiconductor devices.

In recent years, there has been a demand for lower power consumption and higher operating speed of semiconductor devices. In order to achieve higher operating speed of a semiconductor device, a method of increasing the gate capacitance of a Metal Insulator Semiconductor Field Effect Transistor (MISFET) to increase a drive current has been employed. The increase of the gate capacitance requires a reduction in the distance between electrodes (a substrate and a gate electrode) by reducing the thickness of a gate insulating film. To meet this requirement, the physical thickness of the gate insulating film of the MISFET is currently reduced to as small as about 2 nm when the gate insulating film is made of silicate nitride (SiON). However, the reduction in the thickness of the gate insulating film leads to an increase in gate leakage, which is a significant problem. It has been contemplated to use a high-k material having a high dielectric constant, such as an oxide containing Hf or the like, as a material for the gate insulating film instead of a silicate oxide (SiO₂)-based material so as to reduce gate leakage while reducing the thickness of the gate insulating film.

Moreover, the reduction in the thickness of the gate insulating film also leads to a problem with conventional gate electrodes made of polycrystalline silicon that depletion occurs in the gate electrode and therefore the gate capacitance conversely decreases. A reduction in the gate capacitance due to the depletion in the gate electrode, for example, corresponds to an increase of about 0.5 nm in the thickness of the gate insulating film made of silicate oxide (SiO₂). If the depletion in the gate electrode can be reduced, the effective thickness of the gate insulating film can be reduced without an increase in the gate leakage. When the gate insulating film is made of SiO₂, the if the film thickness is reduced by 0.1 nm, the leakage current is increased by a factor of 10 or more as compared to before the film thickness is reduced. Therefore, by reducing the depletion in the gate electrode, the effect of decreasing the effective thickness of the gate insulating film can be significantly increased.

It has been contemplated that polycrystalline silicon as a material for the gate electrode is replaced with a metal which does not cause depletion to avoid the depletion in the gate electrode. Polycrystalline silicon can be used to form both electrodes for p-MISFET and n-MISFET, because an impurity level is formed in polycrystalline silicon by implanting an impurity. On the other hand, when a metal is used, electrodes for p-MISFET and n-MISFET cannot both be formed by impurity implantation. Therefore, a metal which has a work function (WF) value corresponding to substantially a center value between the WF value of a p-region and the WF value of an n-region is used as a common material for a p-MISFET electrode and an n-MISFET electrode, and the p-MISFET and the n-MISFET are designed so that they have the same threshold voltage (Vt).

In recent years, higher-speed operation is required. Therefore, a lower threshold voltage is essential, and the p-MISFET electrode and the n-MISFET electrode each need to have a WF value which is close to a band edge of silicon. The band edge as used herein means a high WF close to the work function value of an upper portion (top edge) of the valence band of silicon (about 5.2 eV) with respect to the p-region, and a low WF close to the work function value of a lower portion (bottom edge) of the conduction band of silicon (about 4.1 eV) with respect to the n-region. Therefore, semiconductor devices in which a metal which has a WF value corresponding to substantially a center value between the WF value of the p-region and the WF value of the n-region is used as a material for the p-MISFET and n-MISFET electrodes are becoming impractical.

At present, researches have been extensively carried out to find a metal material which can be used for p-MISFET and n-MISFET gate electrodes. However, it is becoming clear that, even if a material has an appropriate WF at room temperature, its WF is changed by a high-temperature treatment, such as activation of source/drain regions or the like. In recent years, it has been contemplated that a cap material for controlling an effective work function (eWF) is deposited between a high-k film and a gate electrode, and a dipole is formed in a gate insulating film and an interface between the high-k film and a metal, thereby controlling the eWF (see, for example, S. Kubicek et al, “IEDM Tech Dig.,” 2007, p. 49). It is known that lanthanum oxide (LaO) has the effect of reducing the eWF, and therefore, lanthanum oxide is expected as a cap material for forming an n-MISFET gate electrode (see, for example, P. D. Kirsch, “IEDM,” 2006, p. 629).

### SUMMARY

However, the present inventor found a problem that, in a high-density semiconductor device having a channel width of less than 0.4 even if a cap material which reduces the eWF is used to form the n-MISFET gate electrode, the threshold voltage (Vt) cannot be reduced.

In view of the aforementioned problem, the detailed description describes implementations of a semiconductor device in which, even when the channel width is narrow, the eWF is sufficiently reduced and the threshold voltage is low.

To achieve the object, the present disclosure provides a semiconductor device which includes a gate insulating film which has a higher content of a first element in a lower portion thereof than in an upper portion thereof, and a higher content of a second element in an upper portion thereof than in a lower portion thereof.

Specifically, an example semiconductor device includes a gate insulating film formed on a semiconductor substrate and containing a first element and a second element, and a gate electrode formed on the gate insulating film. The gate insulating film has a higher content of the first element in a lower portion thereof than in an upper portion thereof, and a higher content of the second element in an upper portion thereof than in a lower portion thereof.

The example semiconductor device includes the gate insulating film which has a higher content of the first element in a portion thereof closer to the semiconductor substrate than in a portion closer to the gate electrode, and a higher content of the second element in a portion thereof closer to the gate electrode than in a portion thereof closer to the semiconductor substrate. Therefore, the second element which reduces the eWF of the gate electrode is not likely to be diffused from the gate insulating film into the isolation region. Therefore, even when the channel width is narrow, a sufficient amount of the second element is diffused in the gate insulating film, and therefore, the threshold voltage can be reduced.

In the example semiconductor device, the gate insulating film may contain hafnium, silicon and oxygen in addition to the second element, and the first element may be hafnium.

In the example semiconductor device, the first element is preferably zirconium or aluminum.

In the example semiconductor device, the second element is preferably lanthanum, dysprosium, scandium or magnesium.

An example method for fabricating a semiconductor device, includes the steps of (a) forming an insulating film having a higher content of a first element in a lower portion thereof than in an upper portion thereof, on a semiconductor substrate, (b) forming a cap film containing a second element on the insulating film, (c) diffusing the second element into the insulating film, (d) after step (b), forming an electrode film on the semiconductor substrate, and (e) after step (d), forming a first gate electrode and a first gate insulating film by selectively etching the electrode film and the insulating film, respectively.

In the example semiconductor device fabricating method, the second element is diffused into the insulating film which has a higher content of the first element in a lower portion thereof than in an upper portion thereof. Therefore, even when the channel width is narrow, the diffusion of the second element from the insulating film into the isolation region can be reduced. Moreover, the diffusion of the second element in the insulating film is not inhibited, and therefore, the eWF of the gate electrode can be reduced, so that the threshold voltage can be sufficiently reduced.

The example semiconductor device fabricating method may further include the step of (f) after step (c), removing a remaining portion of the cap film. In this case, step (d) may be performed after step (f).

In the example semiconductor device fabricating method, step (c) may be performed after step (e).

The example semiconductor device fabricating method may further include the steps of (g) before step (a), forming a first region and a second region separated from each other, in the semiconductor substrate, and (h) between step (a) and step (b), forming an intermediate electrode film on the second region. Step (e) may include forming the first gate electrode and the first gate insulating film in the first region, and forming a second gate electrode and a second gate insulating film in the second region by selectively removing the electrode film and the insulating film.

In this case, the example semiconductor device fabricating method may further include the step of (i) between step (c) and step (d), removing a region of the intermediate electrode film in which the second element is diffused.

Moreover, the example semiconductor device fabricating method may further include the step of (j) between step (c) and step (d), removing the intermediate electrode film.

In the example semiconductor device fabricating method, step (a) may include forming a first insulating film containing a first element on the semiconductor substrate, and thereafter, forming a second insulating film having a lower content of the first element than that of the first insulating film on the first insulating film.

In the example semiconductor device fabricating method, the gate insulating film may contain hafnium, silicon and oxygen in addition to the second element, and the first element may be hafnium.

In the example semiconductor device fabricating method, the first element is preferably zirconium or aluminum.

In the example semiconductor device fabricating method, the second element is preferably lanthanum, dysprosium, scandium or magnesium.

Thus, the semiconductor device and its fabrication method of the present disclosure can provide a semiconductor device in which, even when the channel width is narrow, the eWF is sufficiently reduced and therefore the threshold voltage is low.

### BRIEF DESCRIPTION OF THE DRAWINGS

FIG. 1 is a graph showing a relationship between a channel width and a threshold voltage.

FIG. 2 is a graph showing a relationship between a Hf composition ratio and an eWF shift amount.

FIG. 3 is a cross-sectional view of a structure of a semiconductor device according to a first embodiment.

FIGS. 4A-4D are cross-sectional views of a method for fabricating the semiconductor device of the first embodiment in the order in which the semiconductor device is fabricated.

FIGS. 5A-5C are cross-sectional views of the method for fabricating the semiconductor device of the first embodiment in the order in which the semiconductor device is fabricated.

FIG. 6 is a cross-sectional view of a structure of a semiconductor device according to a second embodiment.

FIGS. 7A-7D are cross-sectional views of a method for fabricating the semiconductor device of the second embodiment in the order in which the semiconductor device is fabricated.

FIGS. 8A-8D are cross-sectional views of the method for fabricating the semiconductor device of the second embodiment in the order in which the semiconductor device is fabricated.

### DETAILED DESCRIPTION

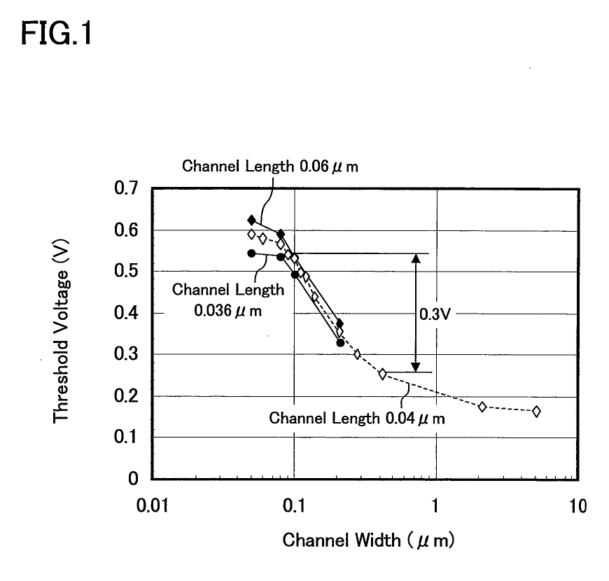

Firstly, a phenomenon that, when the channel width is narrow, the threshold voltage (Vt) cannot be reduced even if a cap material such as lanthanum or the like is used, will be described. FIG. 1 shows a relationship between the channel width and Vt of an n-MISFET in which a cap material containing lanthanum (La) is diffused into the gate insulating film. In FIG. 1, the gate insulating film is made of hafnium silicate (HfSiON) containing nitrogen, and the gate electrode is made of titanium nitride (TiN). As shown in FIG. 1, as the channel width decreases, Vt increases. When the channel width decreases from 0.42 μm to 0.1 μm, the value of Vt increases by about 0.3 V. Moreover, as can be seen from FIG. 1, this phenomenon is not affected by the channel length.

The reason why Vt steeply increases with a decrease in the channel width is inferred as follows. When a cap film made of lanthanum oxide (LaO) which has been deposited on the gate insulating film made of a high-k film containing hafnium (Hf) or the like is subjected to annealing, La is diffused into the gate insulating film. As a result, the effective work function (eWF) can be reduced.

An interface (IL) film made of SiO₂ is present at an interface between the gate insulating film and the silicon substrate. La penetrates the gate insulating film and diffuses to a vicinity of the IL film. The IL film typically has a thickness of about 1 nm. Therefore, when the channel width is broad, even if La is diffused from the gate insulating film into the IL film, the gate insulating film still contains a sufficient amount of La, and therefore, the eWF can be reduced.

However, the IL film also contacts the isolation region. The isolation region is made of a SiO₂ film having substantially an infinite size as compared to the IL film. Therefore, as the channel width decreases, La is diffused into the isolation region without a limitation, and therefore, almost no La remains at the interface between the gate insulating film and the IL film. This may be the reason why Vt increases with a decrease in the channel width.

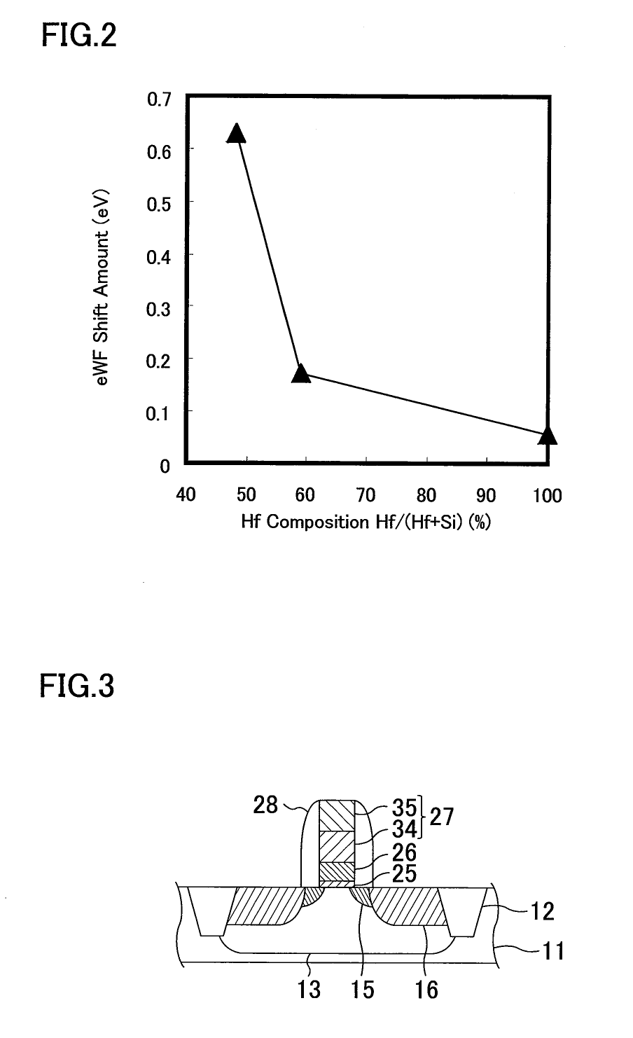

In order to reduce the increase in Vt, it is necessary to reduce the diffusion of La into the isolation region. FIG. 2 shows a relationship between the composition of the gate insulating film and the shift amount of the eWF. In FIG. 2, the horizontal axis indicates the percentage of Hf with respect to the total sum of Hf and Si contained in the gate insulating film. Gate insulating films having different values of Hf/(Hf+Si) were formed by changing the composition ratio of Si in HfSiON. Note that Hf/(Hf+Si)=100% corresponds to a case where hafnium oxide (HfO₂) which does not contain Si was used. The vertical axis indicates the shift amount of the eWF which was obtained when LaO having a thickness of 1 nm was formed on the gate insulating film, a gate electrode made of a TiN film and a polysilicon film was then formed, and spike annealing was then performed at 1050° C.

As can be seen from FIG. 2, there is almost no shift in the eWF when the Hf content of the gate insulating film is high, and the shift amount of the eWF increases with a decrease in the Hf content. This indicates that, as the Hf content increases, it is more difficult to diffuse La. Note that, when the LaO film was deposited on the gate insulating film and annealing was then performed at 800° C. for 10 min, the shift amount of the eWF was larger in a region in which the Hf content was high than when only spike annealing was performed. However, as in the case where only spike annealing was performed, a phenomenon that the shift amount of the eWF decreases with an increase in the Hf content was observed. A similar result is obtained when hafnium silicate (HfSiO), which does not contain nitrogen, is used, as well as when HfSiON is used. Also in the case of aluminum oxide (AlO), zirconium oxide (ZrO) or the like, a phenomenon that, as the Al or Zr content increases, it is more difficult to diffuse La, is observed. Moreover, in addition to La, the diffusibility of scandium (Sc), dysprosium (Dy), magnesium (Mg) and the like can be controlled by the content of Hf or the like.

As described above, in order to reduce the diffusion of La into the isolation region to reduce an increase in Vt even when the channel width is narrow, it is preferable to increase the amount of Hf contained in the gate insulating film. However, if the Hf content of the entire gate insulating film is increased, La is not diffused to the interface between the gate insulating film and the IL film, and therefore, Vt cannot be reduced. Therefore, it is preferable to relatively decrease the Hf content in an upper portion of the gate insulating film to make it easy to diffuse La, and relatively increase the Hf content in a lower portion thereof to make it difficult to diffuse La. Based on the aforementioned findings, embodiments of the present disclosure will be described hereinafter.

### First Embodiment

A first embodiment will be described hereinafter with reference to the accompanying drawings. FIG. 3 is a cross-sectional view of a structure of a semiconductor device according to the first embodiment. As shown in FIG. 3, the semiconductor device of this embodiment is an n-MISFET formed on a semiconductor substrate 11, such as a silicon substrate or the like. A p-type active region 13 is formed in the semiconductor substrate 11 and is isolated by an isolation region 12, such as shallow trench isolation (STI) or the like. An underlying (IL) film 25 made of SiO₂ or the like, a gate insulating film 26 made of a high-k film, and a gate electrode 27 are successively formed on the p-type active region 13. An insulating sidewall 28 is formed on each side surface of the gate electrode 27.

Extension regions 15 of n-type are formed in the p-type active region 13 on both sides of the gate electrode 27. Source/drain regions 16 of n-type are formed in the p-type active region 13 adjacent to the respective extension regions 15.

The gate electrode 27 includes a first electrode film 34 made of TiN or the like and a second electrode film 35 made of polysilicon or the like which is formed on the first electrode film 34. The gate insulating film 26 is a hafnium oxide (HfO)-based high-k film, e.g., HfSiO, HfSiON or the like, and contains La which is a cap material. Moreover, the content of Hf, which is a first element, is higher in a portion (lower portion) closer to the semiconductor substrate 11 than in a portion (upper portion) closer to the gate electrode 27. The content of La, which is a second element, is higher in a portion (upper portion) closer to the gate electrode 27 than in a portion (lower portion) closer to the semiconductor substrate 11.

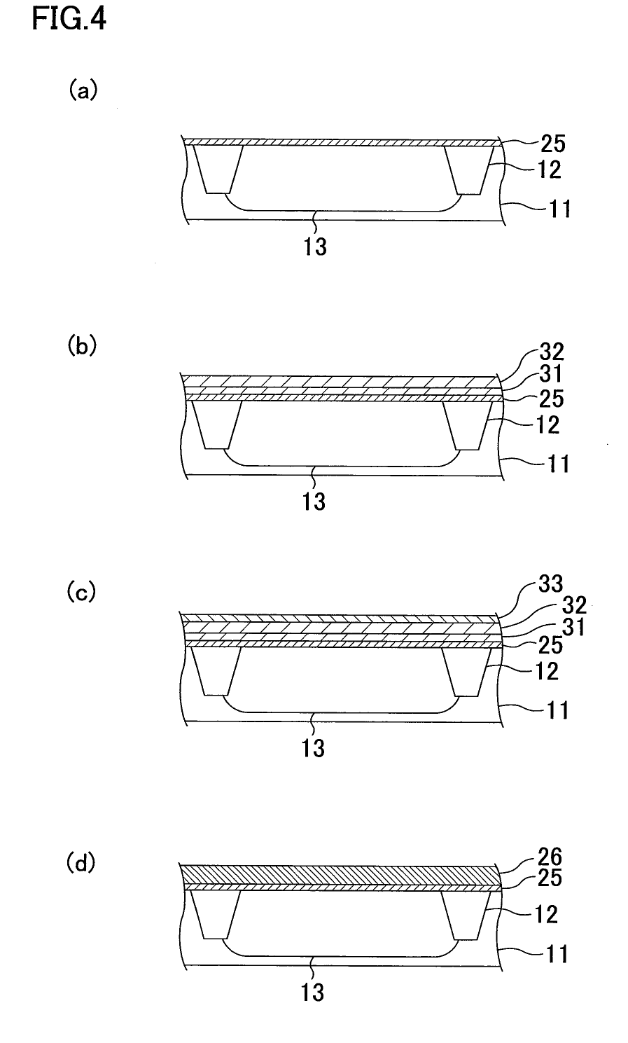

A method for fabricating the semiconductor device of the first embodiment will be described hereinafter with reference to the drawings. Initially, as shown in FIG. 4A, the p-type active region 13 isolated by the isolation region 12 is formed in the semiconductor substrate 11, such as a Si substrate or the like. Thereafter, the underlying film 25 made of SiO₂ having a thickness of about 1 nm is formed on an entire surface of the semiconductor substrate 11. The underlying film 25 may be formed by, for example, rapid thermal oxidation (RTO) using oxygen gas. Note that RTO may be performed using other gas species instead of oxygen gas, and a heating furnace may be used to perform thermal oxidation. The underlying film 25 may be made of silicon oxynitride (SiON), chemical oxide or the like.

Next, as shown in FIG. 4B, a first insulating film 31 having a high Hf composition ratio and a second insulating film 32 having a low Hf composition ratio are formed on the underlying film 25. Specifically, the first insulating film 31 made of HfO₂ having a thickness of 0.4 nm and the second insulating film 32 made of HfSiO (Hf composition ratio: 50%) having a thickness of 1.6 nm are successively deposited by atomic layer deposition (ALD) or the like. For the sake of simplicity, the first and second insulating films 31 and 32 are clearly separated from each other in the drawings. Actually, when HfO₂ and HfSiO are deposited, there is generally not a clearly observed border between the first and second insulating films 31 and 32, i.e., they are integrated together. In particular, when films of HfO₂ and HfSiO are successively formed in the same chamber or when annealing is additionally performed in a subsequent step, the first and second insulating films 31 and 32 are significantly integrated together at the border portion, resulting in a high-k film having a graded composition in which the HF density increases toward the lower portion.

The amount of La diffused to the interface with the IL film in the case of the HfO₂ film having a Hf composition ratio of 100% is about 7% of that in the case of the HfSiO film having a Hf composition ratio of 50%, as estimated from the eWF shift amount. Therefore, when the first insulating film 31 is a HfO₂ film, 0.4 nm is enough thickness for the first insulating film 31 to serve as a film for reducing the diffusion of La.

The dielectric constant (k-value) of HfSiO having a Hf composition ratio of 50% is about 14. The k-value of a HfO₂ film is about two times as high as that of a HfSiO film having a Hf composition ratio of 50%, although it varies, depending on the nitridation conditions or the like. Therefore, the combination of the underlying film 25 made of SiO₂ having a thickness of 1 nm, a HfO₂ film having a thickness of 0.4 nm, and a HfSiO film having a thickness of 1.6 nm has an equivalent oxide thickness (EOT) of about 1.4 nm.

The thickness of the first insulating film 31 may be changed, depending on the Hf composition ratio. For example, when the first insulating film 31 has a Hf composition ratio of 80%, its thickness may be 0.8 nm. In this case, in order to obtain an EOT of 1.4 nm, the thickness of the second insulating film 32 having a Hf composition ratio of 50% may be 1.3 nm. Thus, the compositions and thicknesses of the first and second insulating films 31 and 32 may be changed and combined as appropriate.

Next, as shown in FIG. 4C, after plasma nitridation is performed from a surface of the second insulating film 32, a cap film 33 made of a LaO film having a thickness of 1 nm is formed. The thickness of the cap film 33 may be changed, depending on a required eWF value. In general, the eWF decreases with an increase in the thickness of the cap film, i.e., the eWF increases with a decrease in the thickness of the cap film. The cap film 33 may be deposited by physical vapor deposition (PVD), or alternatively, ALD or the like.

Next, as shown in FIG. 4D, annealing is performed at 600° C. for 10 min to diffuse La contained in the cap film 33 into the first and second insulating films 31 and 32, thereby forming the gate insulating film 26. Next, extra LaO which has not been diffused into the gate insulating film 26 in the annealing process is removed. The removal of extra LaO may be achieved by any technique. For example, the gate insulating film 26 may be washed using dilute hydrochloric acid (dHCl) which is a 1000-fold dilution of hydrochloric acid (concentration: 37 mass %), for 10 sec. The dilution ratio and washing time may be changed as appropriate, depending on the thickness of the LaO film, a thermal treatment time, or the like.

Although a sufficient amount of La is diffused into the upper second insulating film 32 having a low Hf composition ratio, substantially no La is diffused into the lower first insulating film 31 having a high Hf composition ratio. Therefore, the gate insulating film 26 is obtained in which the Hf content is higher in a lower portion thereof than in an upper portion thereof and the La content is higher in an upper portion thereof than in a lower portion thereof. The temperature and time of the annealing process may be changed as appropriate, depending on a required eWF value and the compositions, thicknesses and the like of the first and second insulating films 31 and 32.

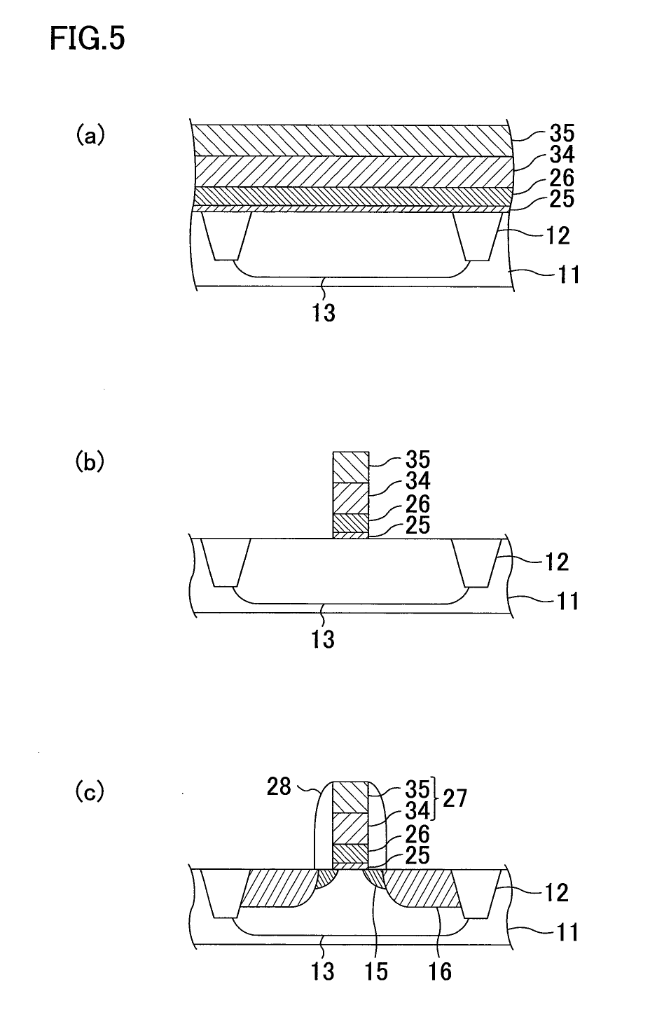

Next, as shown in FIG. 5A, the first electrode film 34 made of TiN and the second electrode film 35 made of polysilicon are successively deposited. Next, an impurity is implanted into the second electrode film 35. Instead of implanting an impurity into the second electrode film 35, a polysilicon film doped with the impurity may be deposited.

The first electrode film 34 may be made of any material that can be combined with a cap material to obtain an appropriate eWF, including, for example, tantalum nitride (TaN) and the like. Moreover, the second electrode film 35 is made of polysilicon and has a metal-inserted poly-silicon stack (MIPS). Alternatively, the second electrode film 35 may be made of a metal film, thereby providing a full-metal gate electrode. Moreover, the second electrode film 35 may be omitted.

Next, as shown in FIG. 5B, the underlying film 25, the gate insulating film 26, the first electrode film 34 and the second electrode film 35 are selectively etched by lithography and reactive ion etching (RIE).

Next, as shown in FIG. 5C, the n-type extension regions 15, the sidewalls 28 and the n-type source/drain regions 16 are formed, the impurity is activated, and the like. Moreover, silicidation may be performed with respect to the polysilicon film, the source/drain regions and the like as required.

According to the semiconductor device of this embodiment and its fabrication method, a gate insulating film is formed in which the Hf content is higher in a lower portion thereof than in a higher portion thereof. Therefore, a sufficient amount of La which is a cap material is diffused into the upper portion having a low Hf content of the gate insulating film, to reach a vicinity of an interface between the gate insulating film and the underlying film. However, the diffusion of La is reduced in the lower portion having a high Hf content of the gate insulating film, whereby the diffusion of La into the underlying film can be reduced. Therefore, the effect of reducing the eWF by the cap material can be exhibited even in a semiconductor device having a narrow channel width which easily causes diffusion from the underlying film into the isolation region. Therefore, the threshold voltage can be reduced to a low level even in a high-density n-MISFET having a channel width of less than 0.4

In this embodiment, the annealing process for diffusing the cap material is performed prior to formation of the first electrode film. However, when the first film which is a diffusion preventing layer has a relatively low Hf content, the diffusion of the cap material is facilitated. Therefore, the cap material can be diffused by spike annealing or the like which is performed when a device is formed, without additionally performing the annealing process for diffusing the cap material. Therefore, the annealing process for diffusing the cap material may be omitted.

### Second Embodiment

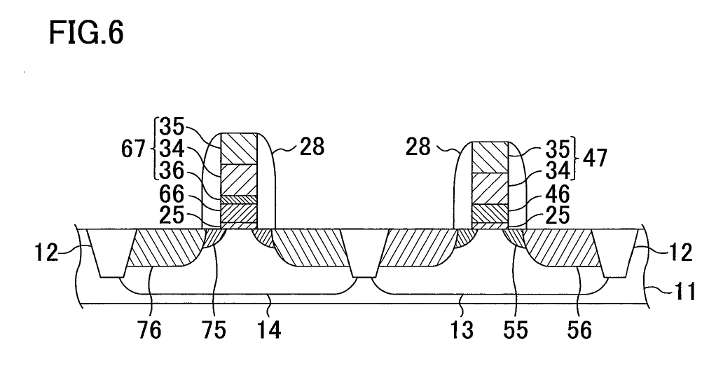

A second embodiment will be described hereinafter with reference to the drawings. FIG. 6 is a cross-sectional view of a structure of a semiconductor device according to the second embodiment. In FIG. 6, the same components as those of FIG. 3 are indicated by the same reference characters and will not be described.

As shown in FIG. 6, the semiconductor device of the second embodiment has a complementary MIS (CMIS) structure which includes an n-MISFET and a p-MISFET.

A p-type active region 13 and an n-type active region 14, which are isolated by an isolation region 12, such as STI, are formed in a semiconductor substrate 11, such as a Si substrate or the like.

An underlying film 25 made of SiO₂ or the like, a first gate insulating film 46 made of a high-k film, and a first gate electrode 47 are successively formed on the p-type active region 13. A sidewall 28 is formed on each side surface of the first gate electrode 47.

First extension regions 55 of n-type are formed in the p-type active region 13 on both sides of the first gate electrode 47. First source/drain regions 56 on n-type are formed in the p-type active region 13 adjacent to the respective first extension regions 55.

An underlying film 25 made of SiO₂ or the like, a second gate insulating film 66 made of a high-k film, and a second gate electrode 67 are successively formed on the n-type active region 14. A sidewall 28 is formed on each side surface of the second gate electrode 67.

Second extension regions 75 of p-type are formed in the n-type active region 14 on both sides of the second gate electrode 67. Second source/drain regions 76 of p-type are formed adjacent to the respective second extension regions 75.

The first gate electrode 47 includes a first electrode film 34 made of TiN or the like and a second electrode film 35 made of polysilicon or the like which is formed on the first electrode film 34. The second gate electrode 67 includes an intermediate electrode film 36 made of TiN or the like, a first electrode film 34 made of TiN or the like, and a second electrode film 35 made of a polysilicon film. The second gate electrode 67 is higher than the first gate electrode 47 by a height of the intermediate electrode film 36.

The first and second gate insulating films 46 and 66 are each made of a hafnium oxide (HfO)-based high-k film, e.g., HfSiO, HfSiON or the like. The first gate insulating film 46 contains La which is a cap material. The second gate insulating film 66 contains no or substantially no La. Moreover, in the first and second gate insulating films 46 and 66, the Hf content is higher in a lower portion thereof than in an upper portion thereof. Moreover, in the first gate insulating film 46, the La content is higher in an upper portion thereof than in a lower portion thereof.

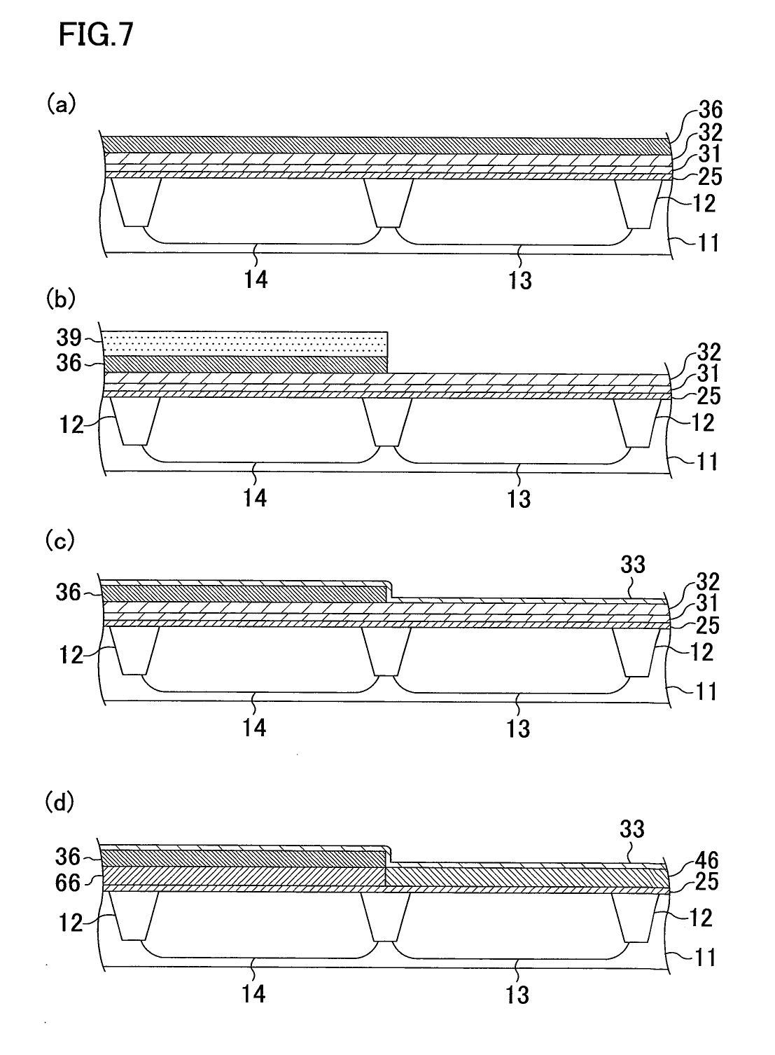

A method for fabricating the semiconductor device of the second embodiment will be described hereinafter with reference to the drawings. Initially, as shown in FIG. 7A, the p-type active region 13 isolated by the isolation region 12 is formed in the semiconductor substrate 11, such as a Si substrate or the like. Thereafter, the underlying film 25 made of SiO₂ having a thickness of about 1 nm is formed on an entire surface of the semiconductor substrate 11. The underlying film 25 may be formed by, for example, rapid thermal oxidation (RTO) using oxygen gas. Note that RTO may be performed using other gas species instead of oxygen gas, and a heating furnace may be used to perform thermal oxidation. The underlying film 25 may be made of silicon oxynitride (SiON), chemical oxide or the like.

Next, a first insulating film 31 having a high Hf composition ratio and a second insulating film having a low Hf composition ratio are formed on the underlying film 25. Specifically, the first insulating film 31 made of HfO₂ having a thickness of 0.4 nm and the second insulating film 32 made of HfSiO (Hf composition ratio: 50%) having a thickness of 1.6 nm are successively deposited by atomic layer deposition (ALD) or the like. Moreover, plasma nitridation is performed with respect to the second insulating film 32. For the sake of simplicity, the first insulating film 31 and the second insulating film 32 are clearly separated from each other in the drawings. Actually, when HfO₂ and HfSiO are deposited, there is not a clearly observed border between the first and second insulating films 31 and 32, i.e., they are integrated together.

Next, the intermediate electrode film 36 made of a TiN film having a thickness of about 5 nm is formed on the second insulating film 32.

Next, as shown in FIG. 7B, a resist film 39 is formed, covering the n-type active region 14. Thereafter, a portion of the intermediate electrode film 36 on the p-type active region 13 is removed using the resist film 39 as a mask.

Next, as shown in FIG. 7C, after the resist film 39 is removed by washing using a thinner, the cap film 33 made of LaO having a thickness of 1 nm is formed on an entire surface of the semiconductor substrate 11.

Next, as shown in FIG. 7D, a thermal treatment is performed at 800° C. for 10 min. As a result, La is thermally diffused from the cap film 33. As a result, on the p-type active region 13, the first gate insulating film 46 is formed in which the Hf content is higher in a lower portion thereof than in an upper portion thereof and the La content is higher in an upper portion thereof than in a lower portion thereof. On the other hand, on the n-type active region 14, La is diffused into only an upper portion of the intermediate electrode film 36, and is not diffused into the first insulating film 31 or the second insulating film 32. Therefore, the second gate insulating film 66 in which La is not diffused is formed. The temperature and time of the annealing process may be changed, as appropriate, depending on a required eWF value and the compositions, thicknesses and the like of the first and second insulating films 31 and 32.

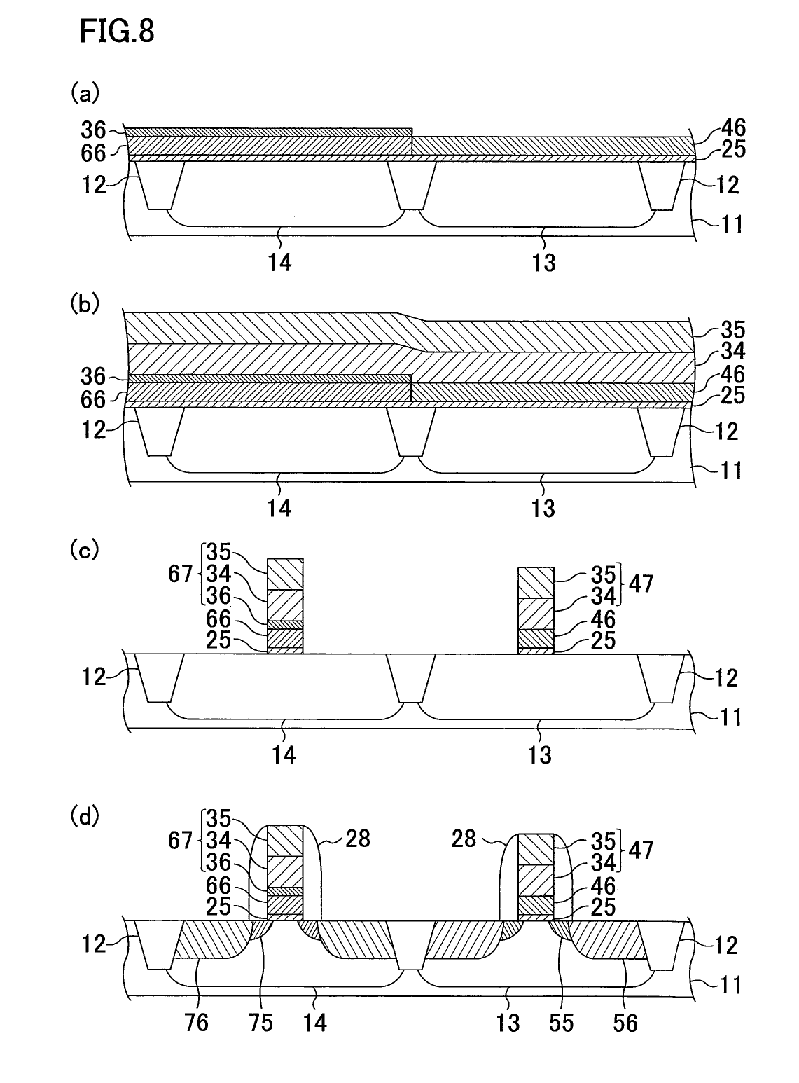

Next, as shown in FIG. 8A, extra LaO which has not been diffused into the gate insulating film 26 in the annealing process is removed. The removal of extra LaO may be achieved by any technique. For example, the gate insulating film 26 may be washed using dilute hydrochloric acid (dHCl) which is a 1000-fold dilution of hydrochloric acid (concentration: 37 mass %), for 10 sec. The dilution ratio and washing time may be changed as appropriate, depending on the thickness of the LaO film, a thermal treatment time, or the like. Next, a region of the intermediate electrode film 36 in which the cap material is diffused is removed.

The removal of the region of the intermediate electrode film 36 in which the cap material is diffused is performed so as to reduce the cap material which is diffused into the second gate insulating film to reduce the eWF of the p-MISFET. Therefore, when the thickness of the intermediate electrode film 36 is sufficiently large or the intermediate electrode film 36 is made of a material which makes it difficult to diffuse the cap material, the removal of the region in which the cap material is diffused does not have to be performed.

It has been experimentally demonstrated that, when the intermediate electrode film 36 is made of a TiN film and the cap film 33 is made of a LaO film, La is diffused by about 3 nm by a thermal treatment at 800° C. for 10 min. Therefore, if the thickness of the intermediate electrode film 36 is 8 nm or more, the removal of the region in which the cap material is diffused does not have to be performed.

The removal of the region in which the cap material is diffused may be performed by any technique if this can be achieved without degrading the first gate insulating film 46. When the intermediate electrode film 36 is made of a TiN film and the cap film 33 is made of a LaO film, hydrogen peroxide water (H₂O₂) may be used to remove the region. Alternatively, sulfuric acid-hydrogen peroxide mixture (SPM), ammonia-hydrogen peroxide mixture (APM) or the like may be used.

Next, as shown in FIG. 8B, the first electrode film 34 made of TiN and the second electrode film 35 made of polysilicon are successively deposited on an entire surface of the semiconductor substrate 11. Next, an impurity is implanted into the second electrode film 35. Instead of implanting an impurity into the second electrode film 35, a polysilicon film doped with the impurity may be deposited.

Next, as shown in FIG. 8C, the underlying film 25, the first gate insulating film 46, the first electrode film 34 and the second electrode film 35 are selectively etched in the p-type active region 13, and the underlying film 25, the second gate insulating film 66, the intermediate electrode film 36, the first electrode film 34 and the second electrode film 35 are selectively etched in the n-type active region 14, using lithography and reactive ion etching (RIE). As a result, the first gate insulating film 46, and the first gate electrode 47 including the first electrode film 34 made of TiN and the second electrode film 35 made of polysilicon, are formed on the p-type active region 13. Moreover, the second gate insulating film 66, and the second gate electrode 67 including the intermediate electrode film 36 made of TiN, the first electrode film 34 made of TiN and the second electrode film 35 made of polysilicon, are formed on the n-type active region 14.

Next, as shown in FIG. 8D, the n-type first extension regions 55, the p-type second extension regions 75, the sidewalls 28, the n-type first source/drain regions 56, the p-type second source/drain regions 76 and the like are formed. Moreover, the impurity introduced into the first source/drain regions 56 and the second source/drain regions 76 are activated to form an n-MISFET in the p-type active region 13 and a p-MISFET in the n-type active region 14.

In this embodiment, the first and second gate electrodes 47 and 67 are each a multilayer film including a TiN film and a polysilicon film. In this case, silicidation may be performed with respect to at least a portion of the polysilicon film. As a result, the resistances of the first and second gate electrodes 47 and 67 can be reduced. Moreover, the second electrode film 35 may be made of a metal film instead of the polysilicon film, or alternatively, can be omitted.

The semiconductor device of this embodiment may be fabricated as follows. Initially, a thermal treatment is performed in a state in which the second insulating film 32 contacts the cap film 33 in the n-MISFET and the intermediate electrode film 36 is interposed between the second insulating film 32 and the cap film 33 in the p-MISFET, and thereafter, the cap film 33 is removed. Therefore, the first gate insulating film 46 of the n-MISFET made of a high-k film in which the cap material for reducing the eWF is diffused, and the second gate insulating film of the p-MISFET made of a high-k film in which La is not diffused (i.e., the eWF is not changed), can be formed without selectively processing the cap film 33.

Moreover, the first insulating film 31 having a high Hf content and the second insulating film 32 having a low Hf content are successively stacked from the semiconductor substrate 11, and therefore, the first and second gate insulating films 46 and 66 each have a higher Hf content in a lower portion thereof than in an upper region thereof. Therefore, the cap material is easily diffused in the upper portion of the first gate insulating film 46, and the diffusion is limited in the lower portion. Therefore, even when the channel width is narrow, the cap material is hardly diffused into the isolation region 12, and therefore, the content of the cap material in the first gate insulating film 46 is not reduced. As a result, the threshold voltage Vt can be reduced even in the n-MISFET having a narrow channel width.

Moreover, the second gate electrode 67 of the p-MISFET is a multilayer film including the intermediate electrode film 36 and the first electrode film 34, and therefore, has a greater height than that of the first gate electrode 47 made of the first electrode film 34 of the n-MISFET. As a result, the eWF value of the p-MISFET can be further increased.

The first electrode film 34 and the intermediate electrode film 36 are not limited to a TiN film, and are preferably made of a metal film containing Ti or Ta, such as a TaN film, a TaC film, a TaCN film or the like. Moreover, the first electrode film 34 and the intermediate electrode film 36 may be made of any other metal material that can provide an appropriate eWF when it is combined with a material for the cap film.

The thicknesses of the first electrode film 34 and the intermediate electrode film 36 may be changed as appropriate, depending on the material and the fabrication process. Note that, when the first electrode film 34 and the intermediate electrode film 36 are both made of a TiN film, the sum of the thicknesses of the first electrode film 34 and the intermediate electrode film 36 is preferably 15 nm or more so as to obtain an appropriate eWF value in the p-MISFET.

Moreover, a cap material having the effect of increasing eWF, such as Al or the like, may be diffused into the second gate insulating film 66 of the p-MISFET.

In this embodiment, after diffusion of the cap material, a portion of the intermediate electrode film 36 is left, whereby the second gate electrode 67 has a multilayer film including the first electrode film 34 and the intermediate electrode film 36. However, after diffusion of the cap material, the intermediate electrode film 36 may be completely removed. In this case, the first and second gate electrodes 47 and 67 have the same height, and therefore, the subsequent process is advantageously facilitated. Moreover, when the intermediate electrode film 36 is left, a thin insulating film may be formed at an interface between the intermediate electrode film 36 and the first electrode film 34, and therefore, the gate resistance may be likely to increase. However, when the intermediate electrode film 36 is completely removed, such an increase in the gate resistance is not likely to occur.

In this embodiment, the first insulating film 31, the second insulating film 32 and the first electrode film 34 are not partially removed. Therefore, when the fabrication method of this embodiment is applied to a static RAM (S-RAM) or the like, the first and second gate insulating films 46 and 66 are continuously formed on the isolation region in a border region where the n-MISFET contacts the p-MISFET. Moreover, the first electrode film 34 is also continuously formed.

In the first and second embodiments, it has been described as an example that the cap film is made of LaO. The cap film may be any insulating film that has the effect of reducing the eWF of an electrode. The cap film may be made of an oxide of a lanthanoide-series element, such as dysprosium oxide (DyO) or the like, or alternatively, scandium oxide (ScO), magnesium oxide (MgO) or the like.

It has been described above as an example that the first and second insulating films 31 and 32 are formed by ALD. Alternatively, the first and second insulating films 31 and 32 may be formed by metal organic vapor deposition (MOCVD), chemical vapor deposition (CVD), physical vapor deposition (PVD) or the like. In the case of MOCVD, a film having a high Hf composition ratio and a film having a low Hf composition ratio can be easily formed by changing the deposition temperature and the gas flow ratio. It has also been described above as an example that, after formation of the first and second insulating films 31 and 32, plasma nitridation is performed to form the HfSiON film. Instead of plasma nitridation, annealing may be performed in an ammonia atmosphere. Alternatively, the nitridation process may be omitted, depending on a required dielectric constant and EOT.

It has also been described above as an example that a Hf-based film is used as the high-k film. Alternatively, aluminum, zirconium or the like may be used instead of Hf. Also in this case, the diffusibility of the cap material can be controlled by the composition.

The semiconductor device and its fabrication method of the present disclosure can provide a semiconductor device in which, even when the channel width is narrow, the eWF is sufficiently reduced and therefore the threshold voltage is low, and are particularly useful for a higher-density semiconductor device and its fabrication method.

What is claimed is:

1. A semiconductor device comprising:
a gate insulating film formed on a semiconductor substrate and containing a first element and a second element; and
a gate electrode formed on the gate insulating film,
wherein
the gate insulating film has a higher content of the first element in a lower portion thereof than in an upper portion thereof, and a higher content of the second element in an upper portion thereof than in a lower portion thereof.

2. The semiconductor device of claim 1, wherein
the gate insulating film contains hafnium, silicon and oxygen in addition to the second element, and the first element is hafnium.

3. The semiconductor device of claim 1, wherein
the first element is zirconium or aluminum.

4. The semiconductor device of claim 1, wherein
the second element is lanthanum, dysprosium, scandium or magnesium.

5. A method for fabricating a semiconductor device, comprising the steps of:
(a) forming an insulating film having a higher content of a first element in a lower portion thereof than in an upper portion thereof, on a semiconductor substrate;
(b) forming a cap film containing a second element on the insulating film;
(c) diffusing the second element into the insulating film;
(d) after step (b), forming an electrode film on the semiconductor substrate; and
(e) after step (d), forming a first gate electrode and a first gate insulating film by selectively etching the electrode film and the insulating film, respectively.

6. The method of claim 5, further comprising the step of:
(f) after step (c), removing a remaining portion of the cap film,
wherein
step (d) is performed after step (f).

7. The method of claim 5, wherein
step (c) is performed after step (e).

8. The method of claim 5, further comprising the steps of:
(g) before step (a), forming a first region and a second region separated from each other, in the semiconductor substrate; and
(h) between step (a) and step (b), forming an intermediate electrode film on the second region,
wherein
step (e) includes forming the first gate electrode and the first gate insulating film in the first region, and forming a second gate electrode and a second gate insulating film in the second region by selectively removing the electrode film and the insulating film.

9. The method of claim 8, further comprising the step of:
(i) between step (c) and step (d), removing a region of the intermediate electrode film in which the second element is diffused.

10. The method of claim 8, further comprising the step of:
(j) between step (c) and step (d), removing the intermediate electrode film.

11. The method of claim 5, wherein
step (a) includes forming a first insulating film containing a first element on the semiconductor substrate, and thereafter, forming a second insulating film having a lower content of the first element than that of the first insulating film on the first insulating film.

12. The method of claim 5, wherein
the gate insulating film contains hafnium, silicon and oxygen in addition to the second element, and the first element is hafnium.

13. The method of claim 5, wherein
the first element is zirconium or aluminum.

14. The method of claim 5, wherein
the second element is lanthanum, dysprosium, scandium or magnesium.
